(19) United States
(12) Patent Application Publication
(10) Pub. No.: US 2002/0076888 A1
(43) Pub. Date: Jun. 20, 2002

(54) Method for manufacturing semiconductor device

(75) Inventors: Tatsuya Shiromoto, Tokyo (JP); Satoshi Shimizu, Tokyo (JP)

Correspondence Address: MCDERMOTT, WILL & EMERY, 600 13th Street, N.W., WASHINGTON, DC, 20005-3096, US

(73) Assignee: MITSUBISHI DENKI KABUSHIKI KAISHA

(21) Appl. No.: 09/931,098

(22) Filed: Aug. 17, 2001

(30) Foreign Application Priority Data
Dec. 15, 2000 (JP) 2000-382010

(51) Int. Cl. H01L 21/336

(52) U.S. Cl. 438/299

(57) ABSTRACT

Providing a method for manufacturing a semiconductor device, with which it is possible to maintain an isolation breakdown voltage of a LOCOS isolation area high in a semiconductor device finely integrated.

A method for manufacturing a semiconductor device, in which a source/drain region is formed by ion implantation on a silicon substrate isolated by a LOCOS isolation area, further comprises a mask forming step to form an implantation mask on the LOCOS isolation area. An implantation mask is formed so as to prevent ions implanted at an ion implantation step from passing through the LOCOS isolation area and arriving at the silicon substrate below the LOCOS isolation area.

### BACKGROUND OF THE INVENTION

The present invention relates to a method of manufacturing a semiconductor device, and more particularly, to a method of manufacturing a semiconductor device in which transistors are isolated by LOCOS. As to an element isolation method, a similar manufacturing method is usable in STI as well.

FIGS. 4A-4D are cross sectional views showing manufacturing steps of a conventional semiconductor device. Among these manufacturing steps, first, as shown in FIG. 4A, a surface of an n-type silicon substrate 1 is oxidized to thereby form LOCOS isolation areas 2. Following this, gate electrodes 3 are formed by a conventional method on the surface of the silicon substrate 1 between the LOCOS isolation areas 2. Side walls 4 of silicon oxide are formed on side surfaces of the gate electrodes.

Next, as shown in FIG. 4B, boron ions 7 are implanted into the silicon substrate 1 using the gate electrodes 3 and the LOCOS isolation areas 2 as a mask, whereby p-type first implantation regions 8 are formed.

Next, as shown in FIG. 4C, boron ions or BF₂⁺ions 9 are implanted into the silicon substrate 1 with a low acceleration energy, whereby p-type second implantation regions 10 are formed. Since the boron ions 7 are implanted with low acceleration energy, the first implantation regions 8 are formed shallow from the surface of the silicon substrate 1.

Through these steps, as shown in FIG. 4D, a source/drain region is formed, which includes the gate electrodes 3 and the first and the second implantation regions 8 and 10, on the silicon substrate 1 sandwiched by the LOCOS isolation areas 2. Following this, electrodes and the like are formed by a conventional method, thereby completing a semiconductor device.

In increasingly dense and fine semiconductor devices, the area sizes of the LOCOS isolation areas 2 formed on the silicon substrate 1 become smaller, which in turn leads to a thinning effect that penetration of an oxidation material is difficult, and therefore, the LOCOS isolation areas 2 become thin. Since a peripheral transistor of a flash memory which demands a high voltage for writing/erasing in a memory cell must comprise a high breakdown voltage source/drain, boron ions are implanted with a high acceleration energy for the purpose of forming the first implantation regions 8. Because of this, as shown in FIG. 5, the boron ions 7 implanted with a high acceleration energy pass through the LOCOS isolation areas 2 and form a p-type region under the LOCOS isolation areas

This causes a problem that an isolation breakdown voltage ensured by the LOCOS isolation areas 2 decreases.

### SUMMARY OF THE INVENTION

Noting this, the present invention aims at providing a method of manufacturing a semiconductor device, with which it is possible to maintain an isolation breakdown voltage of a LOCOS isolation area high in semiconductor device integrated dense and fine.

The present invention is directed to a method for manufacturing a semiconductor device in which a source/drain region is formed by ion implantation on a silicon substrate isolated by a LOCOS isolation area, comprising: a step to prepare a silicon substrate; a LOCOS forming step to oxidize a surface of said silicon substrate and to form a LOCOS isolation area; an electrode forming step to form a gate electrode on said silicon substrate on both sides of said LOCOS isolation area; and an ion implantation step to implant ions into the surface of said silicon substrate using said gate electrode as a mask and to form a source region and a drain region so as to sandwich said gate electrode, and characterized in further comprising a mask forming step to form an implantation mask on said LOCOS isolation area, and in that said implantation mask is formed to prevent said ions implanted at said ion implantation step from passing through said LOCOS isolation area and arriving at said silicon substrate below said LOCOS isolation area.

Using this manufacturing method, it is possible to prevent a conductive region from being formed below the LOCOS isolation area, and hence, maintain an isolation breakdown voltage of the LOCOS isolation areas high.

In the method according to the present invention, the mask forming step may comprise: a step to deposit a TEOS layer on the silicon substrate after the electrode forming step; and a step to selectively etch said TEOS layer so that said TEOS layer is left on the LOCOS isolation area and becomes the implantation mask.

With the ion implantation step performed with the TEOS layer formed on the LOCOS isolation area, it is possible to stop the ions implanted into the LOCOS isolation area within the LOCOS isolation area.

In the method according to the present invention, the mask-forming step may comprise: a step to deposit a photoresist layer on the silicon substrate after the electrode forming step; and a step to pattern said photoresist layer so that said photoresist layer is left on the LOCOS isolation area and becomes the implantation mask.

With the ion implantation step performed with the resist mask formed on the LOCOS isolation area, it is possible to stop the ions implanted into the LOCOS isolation area within the LOCOS isolation area.

In the method according to the present invention, the mask forming step may comprise: a step to form a conductive layer and an insulation layer successively on the silicon substrate after the LOCOS forming step; and a step to selectively etch said conductive layer and said insulation layer so that said layers are left on said LOCOS isolation area and become the implantation mask.

Performing the ion implantation step with the conductive layer and the insulation layer formed on the LOCOS isolation area, it is possible to stop the ions implanted into the LOCOS isolation area within the LOCOS isolation area.

The etching step preferably serves also as a step to etch the conductive layer and to form a floating gate of a flash memory.

This is because it is possible to form the implantation mask without increasing the number of manufacturing steps.

The conductive layer is preferably formed by polycrystalline silicon.

The ion implantation step may comprise a first ion implantation step to implant ions with large implantation energy and a second ion implantation step to implant ions with small implantation energy.

After the electrode forming step, a step to form a side wall at a side face of the gate electrode may be performed.

As clearly described above, with the manufacturing method according to the present invention, it is possible to maintain an isolation breakdown voltage of LOCOS isolation areas high even in a semiconductor device integrated in a small size.

### BRIEF DESCRIPTION OF THE DRAWINGS

FIGS. 1A-1F are cross sectional views showing manufacturing steps of a semiconductor device according to the embodiment 1 of the present invention.

FIGS. 2A-2D are cross sectional views showing manufacturing steps of a semiconductor device according to the embodiment 2 of the present invention.

FIGS. 3A-3I are cross sectional views showing manufacturing steps of a semiconductor device according to the embodiment 3 of the present invention.

FIGS. 4A-4D are cross sectional views showing manufacturing steps of a conventional semiconductor device.

FIG. 5 is a cross sectional view of a conventional semiconductor device.

### DETAILED DESCRIPTION OF THE PREFERRED EMBODIMENTS

### Embodiment 1

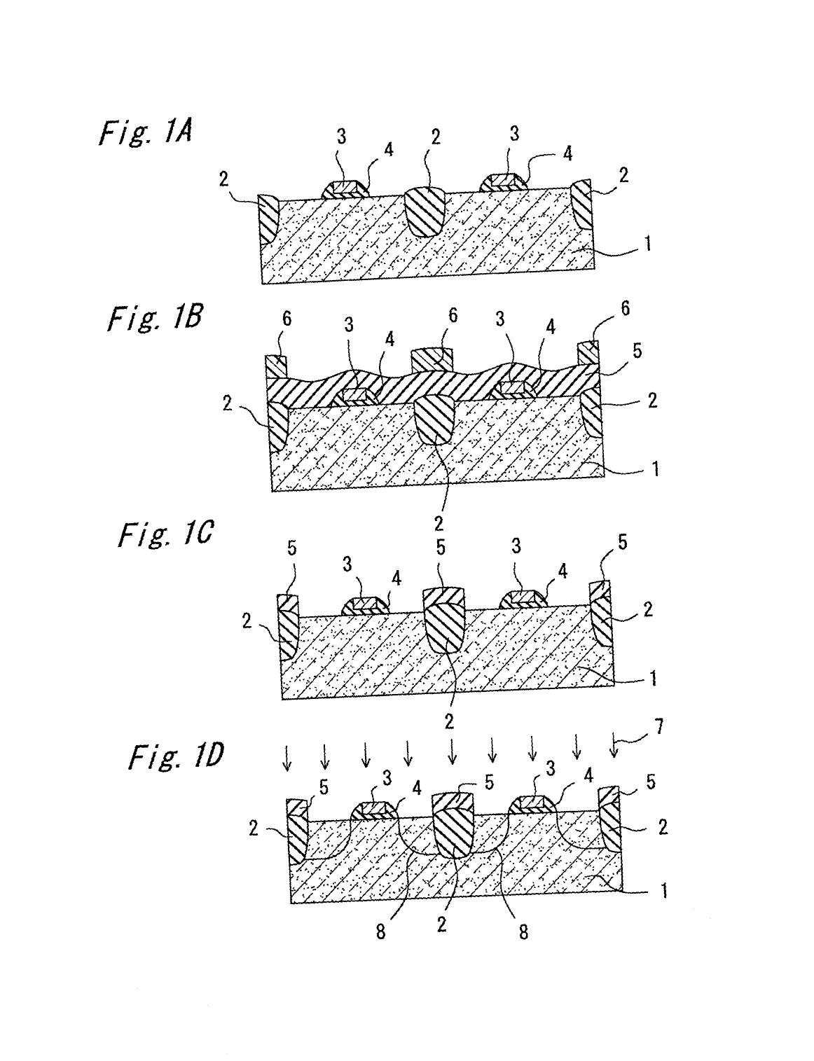

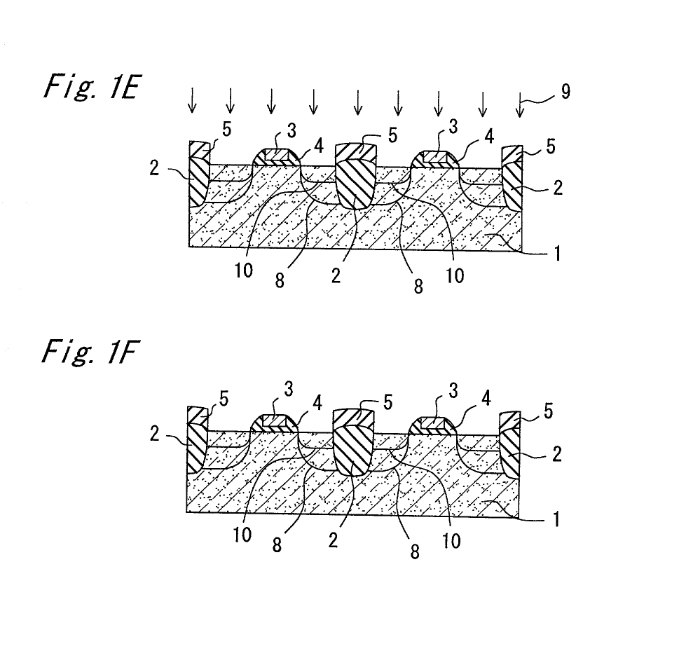

FIGS. 1A-1F are cross sectional views showing manufacturing steps of a semiconductor device according to a preferred embodiment 1 of the present invention. Among these manufacturing steps, first, as shown in FIG. 1A, LOCOS isolation areas 2 are formed on a silicon substrate 1 through a step similar to that customarily practiced. Following this, gate electrodes 3 are formed on the surface the silicon substrate 1 between the LOCOS isolation areas 2. Side walls 4 of silicon oxide are formed at side faces of the gate electrodes.

Next, as shown in FIG. 1B, a TEOS (Tetra Etyle Ortho Silicate) layer 5 is formed by a CVD method so as to cover the surface of the silicon substrate 1.

Following this, a photoresist layer is formed on the TEOS layer 5 and patterned, so that a resist mask 6 is formed above the LOCOS isolation areas 2.

While the resist mask 6 is laid over the LOCOS isolation areas 2 in this embodiment, the resist mask 6 may be wider or narrower than the LOCOS isolation areas 2.

Next, as shown in FIG. 1C, the TEOS layer 5 is selectively removed using the resist mask 6, leaving the TEOS layer 5 only above the LOCOS isolation areas 2. The resist mask 6 is removed after this step.

Next, as shown in FIG. 1D, boron ions 7 are implanted into the silicon substrate 1 with a high acceleration energy, whereby p-type first implantation regions 8 are formed. Since the boron ions 7 are implanted with high acceleration energy, the first implantation regions 8 are formed deep from the surface of the silicon substrate 1. More specifically, the acceleration energy is 20 through 100 keV, while a concentration of the p-type impurity in the first implantation regions 8 is approximately 1×10¹⁰ through 1×10⁻³.

The boron ions 7 entering the LOCOS isolation areas 2 stop within the LOCOS isolation areas 2 and do not travel beyond the LOCOS isolation areas 2.

Next, as shown in FIG. 1E, boron ions 9 are implanted into the silicon substrate 1 with a low acceleration energy, whereby p-type second implantation regions 10 are formed. Since the boron ions 9 are implanted with low acceleration energy, the second implantation regions 10 are formed shallow from the surface of the silicon substrate 1. More specifically, the acceleration energy for boron ions is 1 through 20 keV, the acceleration energy for BF₂ ions is 5 through 40 keV, a concentration of the p-type impurity in the second implantation regions is approximately 1×10¹⁸ through 1×10²² cm⁻³.

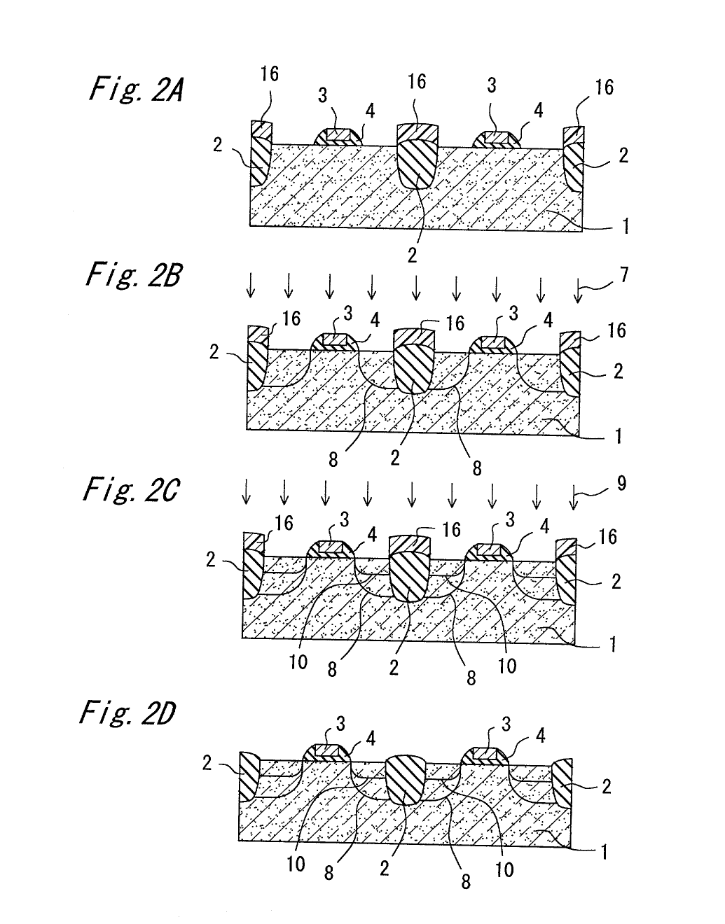

Through these steps, as shown in FIG. 2F, the gate electrodes 3 and source/drain regions which include the first and the second implantation regions 8 and 10 are formed on the silicon substrate 1 sandwiched by the LOCOS isolation areas 2. Following this, electrodes and the like are formed by a conventional method, thereby completing a semiconductor device.

Executing the ion implantation steps in this manner with the TEOS layer 5 formed on the LOCOS isolation areas 2, it is possible to stop the ions implanted into said LOCOS isolation area 2 within said LOCOS isolation area 2. This prevents the implanted ions from passing through the LOCOS isolation areas 2 and forming a p-type region under the LOCOS isolation areas 2 as in the case of the conventional manufacturing method. In consequence, it is possible to maintain an isolation breakdown voltage of the LOCOS isolation areas high.

### Embodiment 2.

FIGS. 2A-2D are cross sectional views showing manufacturing steps of a semiconductor device according to a preferred embodiment 2 of the present invention. Among these manufacturing steps, first, as shown in FIG. 2A, through steps similar to the conventional steps, LOCOS isolation areas 2 and gate electrodes 3 are formed on a silicon substrate 1.

Following this, a photoresist layer (not shown) is formed so as to cover the surface of the silicon substrate 1. The photoresist layer is patterned by a generally used method, whereby a resist mask 16 is formed above the LOCOS isolation areas 2.

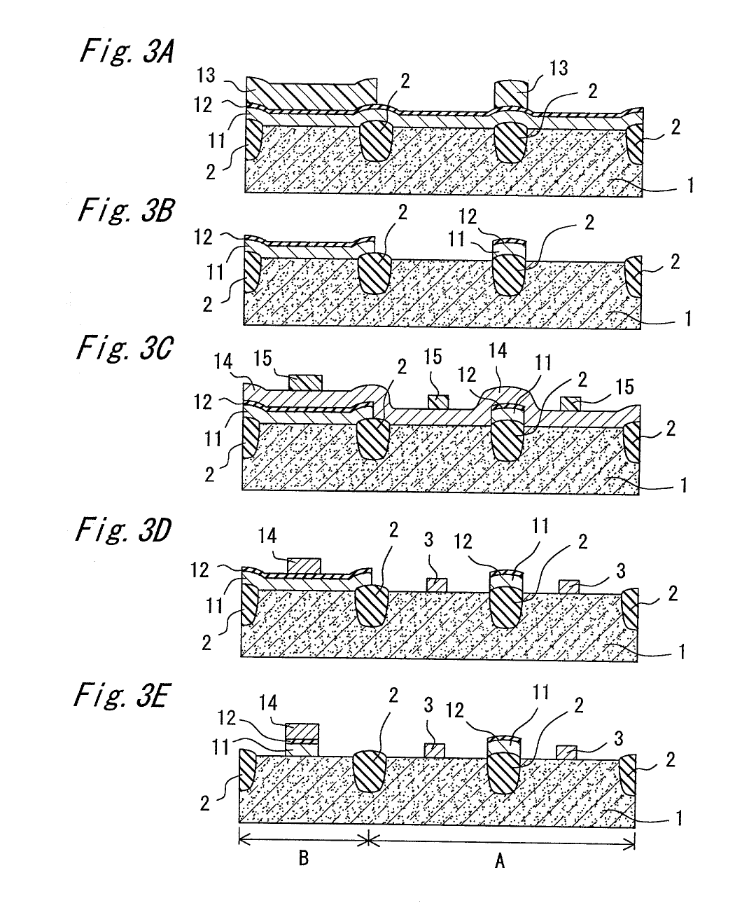

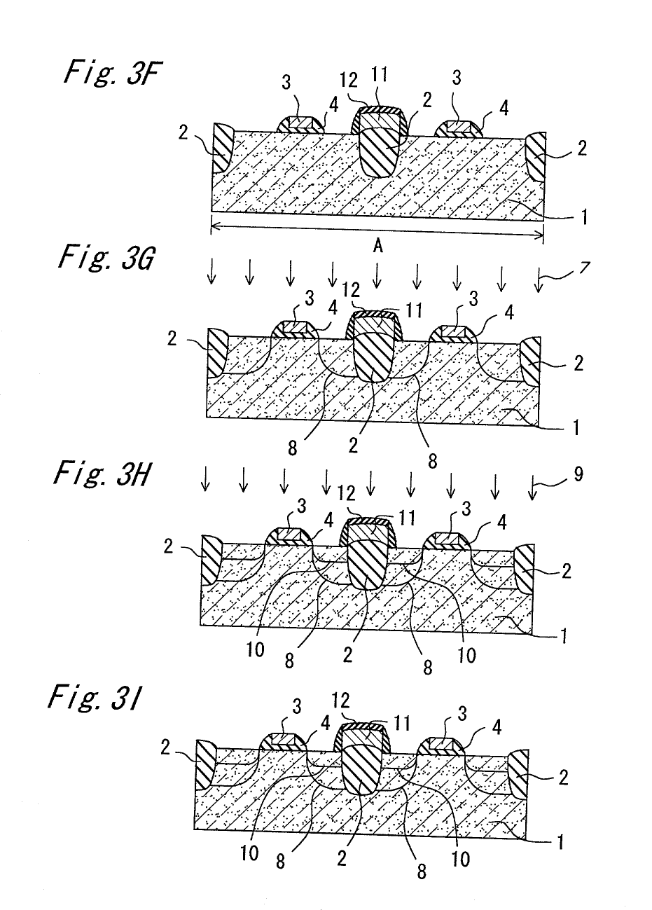

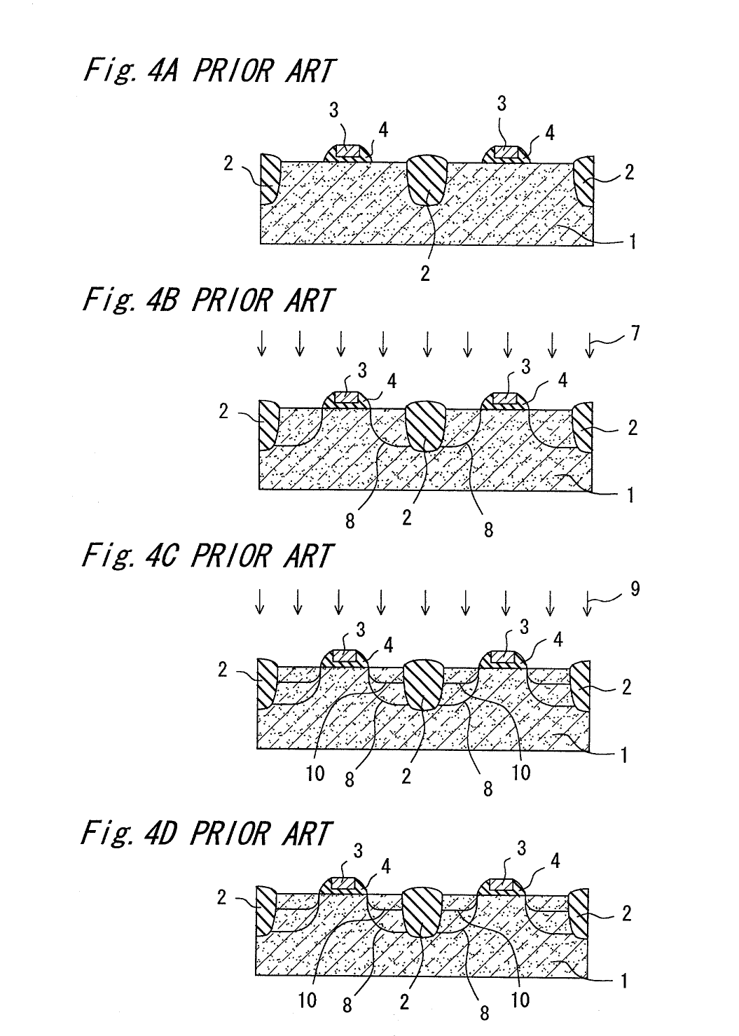

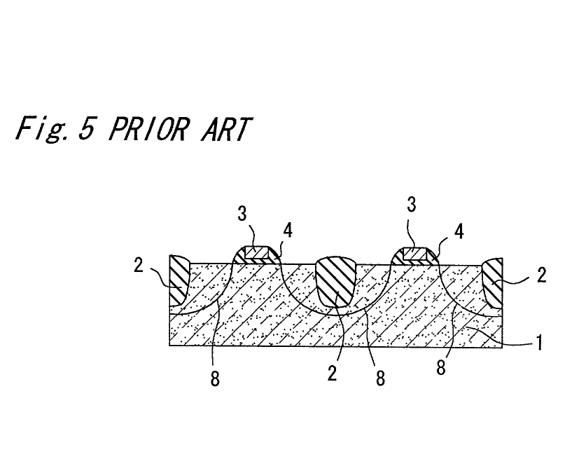

Next, as shown in FIG. 3B, boron ions 7 are implanted into the silicon substrate 1 with a high acceleration energy, whereby p-type first implantation regions 8 are formed. Since the boron ions 7 are implanted with high acceleration energy, the first implantation regions 8 are formed deep from the surface of the silicon substrate 1. More specifically, the acceleration energy is 20 through 100 keV, while a concentration of the p-type impurity in the first implantation regions 8 is approximately 1×10¹⁰ through 1×10¹⁹ cm⁻³.

Next, as shown in FIG. 2C, boron ions 9 are implanted into the silicon substrate 1 with a low acceleration energy, whereby p-type second implantation regions 10 are formed. Since the boron ions 9 are implanted with low acceleration energy, the second implantation regions 10 are formed shallow from the surface of the silicon substrate 1. More specifically, the acceleration energy for boron ions is 1 through 20 keV, the acceleration energy for BF₂ ions is 5 through 40 keV, a concentration of the p-type impurity in the second implantation regions 10 is approximately 1×10¹⁸ through 1×10²² cm⁻³.

Through these steps, as shown in FIG. 2D, the gate electrodes 3 and source/drain regions which include the first and the second implantation regions 8 and 10 are formed on the silicon substrate 1 sandwiched by the LOCOS isolation areas 2. Following this, electrodes and the like are formed by a conventional method, thereby completing a semiconductor device.

Executing the ion implantation steps in this manner with the resist mask 16 formed on the LOCOS isolation areas 2, it is possible to stop the ions implanted into said LOCOS isolation area within said LOCOS isolation area. This prevents the implanted ions from forming a p-type region under the LOCOS isolation areas 2 as in the case of the conventional manufacturing method and makes it possible to maintain an isolation breakdown voltage of the LOCOS isolation areas high.

### Embodiment 3.

FIGS. 3A-3I are cross sectional views showing manufacturing steps of a semiconductor device according to a preferred embodiment 3 of the present invention. The manufacturing steps also serves as some of manufacturing steps for a flash memory.

Among these manufacturing steps, first, as shown in FIG. 3A, through a step similar to that customarily practiced, LOCOS isolation areas 2 are formed on a silicon substrate 1.

Following this, a first gate material layer 11 and an insulation film 12 are formed successively, so as to cover the silicon substrate 1. The first gate material layer 11 is formed by polycrystalline silicon, for instance. Meanwhile, the insulation film 12 is formed by silicon oxide, for example.

After a photoresist layer is then formed covering the insulation film 12, the photoresist layer is patterned, so that a resist mask 13 is formed above the LOCOS isolation areas 2 and above a memory cell formation region. While the resist mask 13 is formed to have the same width as the LOCOS isolation areas 2 as herein described, the resist mask 13 may be formed narrower or wider than the LOCOS isolation areas 2.

Next, as shown in FIG. 3B, using the resist mask 13, the first gate material layer 11 and the insulation film 12 are selectively etched. After the etching step, the resist mask 13 is removed.

Next, as shown in FIG. 3C, a second gate material layer 14 is deposited to cover the silicon substrate 1. The second gate material layer 14 is formed by polycrystalline silicon, for instance.

Following this, a photoresist layer is formed covering the second gate material layer 14. The photoresist layer is then patterned, thereby forming a resist mask 15.

Next, as shown in FIG. 3D, using the resist mask 15, the second gate material layer 14 is selectively etched. The resist mask 15 is thereafter removed.

As a result, a mask formed by the first gate material layer 11 and the insulation film 12 is formed on the LOCOS isolation areas 2.

Next, as shown in FIG. 3E, after covering a transistor region A with a photoresist layer (not shown), the first gate material layer 11 and the insulation film 12 are selectively etched using the second gate material layer 14 as a mask. The photoresist layer is thereafter removed.

In consequence, gate electrodes 3 formed by the second gate material layer 14 is realized in the transistor region A. In a memory cell region B, a stacked layer structure is formed which includes the first gate material layer 11, the insulation film 12 and the second gate material layer 14. The first gate material layer 11 and the second gate material layer 14 become a floating gate and a control gate, respectively, of a flash memory.

While a gate oxide film is formed between the gate electrodes 3 and the silicon substrate 1, FIGS. 3A through 3E omit this.

Next, as shown in FIG. 3F, side walls 4 are formed at side faces of the gate electrodes 3 within the transistor region A. At this step, side walls are formed at side faces of the stacked layer structure, too, within the memory cell region B (not shown).

Steps in FIGS. 3F through 3I are steps related to the transistor region A, and therefore, show only the transistor region A.

Next, as shown in FIG. 3G, boron ions 7 are implanted into the silicon substrate 1 with a high acceleration energy, whereby p-type first implantation regions 8 are formed. Since the boron ions 7 are implanted with high acceleration energy, the first implantation regions 8 are formed deep from the surface of the silicon substrate 1. More specifically, the acceleration energy is 20 through 100 keV, while a concentration of the p-type impurity in the first implantation regions 8 is approximately 1×10¹⁶ through 1×10¹⁹ cm⁻³.

Next, as shown in FIG. 3H, boron ions 9 are implanted into the silicon substrate 1 with a low acceleration energy, whereby p-type second implantation regions 10 are formed. Since the boron ions 9 are implanted with low acceleration energy, the second implantation regions 10 are formed shallow from the surface of the silicon substrate 1. More specifically, the acceleration energy for boron ions is 1 through 20 keV, the acceleration energy for BF₂ ions is 5 through 40 keV, a concentration of the p-type impurity in the second implantation regions 10 is approximately 1×10¹⁸ through 1×10²² cm⁻³.

Through these steps, as shown in FIG. 3I, the gate electrodes 3 and source/drain regions which include the first and the second implantation regions 8 and 10 are formed on the silicon substrate 1 sandwiched by the LOCOS isolation areas 2. Following this, electrodes and the like are formed by a conventional method, thereby completing a semiconductor device.

Executing the ion implantation steps in this manner with the mask comprised of the first gate material layer 11 and the insulation film 12 formed on the LOCOS isolation areas 2, it is possible to stop the ions implanted into said LOCOS isolation area within said LOCOS isolation area. This prevents creation of a p-type region under the LOCOS isolation areas 2 and allows maintaining an isolation breakdown voltage of the LOCOS isolation areas high.

Particularly since the mask comprised of the first gate material layer 11 and the insulation film 12 is formed through manufacturing steps for a flash memory, the mask is obtained without increasing the number of manufacturing steps.

While the foregoing has described the embodiments 1 through 3 in relation to the manufacturing steps for forming the side walls 4 at the side faces of the gate electrodes 3, the side walls 4 may not be formed.

Further, while the foregoing has described an example that the ion implantation step includes the first ion implantation step and the second ion implantation step, the source/drain region may be formed only through the first ion implantation step.

What is claimed is:

1. A method for manufacturing a semiconductor device in which a source/drain region is formed by ion implantation on a silicon substrate isolated by a LOCOS isolation area, comprising:
a step to prepare a silicon substrate;
a LOCOS forming step to oxidize a surface of said silicon substrate and to form a LOCOS isolation area;
an electrode forming step to form a gate electrode on said silicon substrate on both sides of said LOCOS isolation area; and
an ion implantation step to implant ions into the surface of said silicon substrate using said gate electrode as a mask and to form a source region and a drain region so as to sandwich said gate electrode, and
further comprising a mask forming step to form an implantation mask on said LOCOS isolation area, so that said implantation mask is formed to prevent said ions implanted at said ion implantation step from passing through said LOCOS isolation area and arriving at said silicon substrate below said LOCOS isolation area.

2. The method according to claim 1, wherein said mask-forming step comprises:
a step to deposit a TEOS layer on said silicon substrate after said electrode forming step; and
a step to selectively etch said TEOS layer so that said TEOS layer is left on said LOCOS isolation area and becomes said implantation mask.

3. The method according to claim 1, wherein said mask forming step comprises:
a step to deposit a photoresist layer on said silicon substrate after said electrode forming step; and
a step to pattern said photoresist layer so that said photoresist layer is left on said LOCOS isolation area and becomes said implantation mask.

4. The method according to claim 1, wherein said mask forming step comprises:
a step to form a conductive layer and an insulation layer successively on said silicon substrate after said LOCOS forming step; and
a step to selectively etch said conductive layer and said insulation layer so that said layers are left on said LOCOS isolation area and become said implantation mask.

5. The method according to claim 4, wherein said etching step also serves as a step to etch said conductive layer and to form a floating gate of a flash memory.

6. The method according to claim 4, wherein said conductive layer is made from polycrystalline silicon.

7. The method according to claims 1, wherein said ion implantation step comprises:
a first ion implantation step to implant ions with a large implantation energy; and
a second ion implantation step to implant ions with a small implantation energy.

8. The method according to claims 1, further comprising a step to form a side wall at a side face of said gate electrode after said electrode forming step.
